(19) United States
(12) Patent Application Publication
(10) Pub. No.: US 2016/0322272 A1
(43) Pub. Date: Nov. 3, 2016

(54) INTEGRATED FILM, FILM, METHOD FOR PRODUCING SEMICONDUCTOR DEVICE, AND METHOD FOR PRODUCING CHIP

(71) Applicant: NITTO DENKO CORPORATION, Osaka (JP)

(72) Inventors: Naohide TAKAMOTO, Osaka (JP); Ryuichi KIMURA, Osaka (JP)

(73) Assignee: NITTO DENKO CORPORATION, Osaka (JP)

(21) Appl. No.: 15/140,582

(22) Filed: Apr. 28, 2016

(30) Foreign Application Priority Data
Apr. 30, 2015 (JP) 2015-093142

(51) Int. Cl. H01L 23/29; H01L 21/78; B32B 37/14; H01L 21/683

(52) U.S. Cl. CPC H01L 23/293; H01L 21/6836; H01L 21/78; B32B 37/14; H01L 2221/68327; H01L 2221/68386; B32B 2457/14

(57) ABSTRACT

Disclosed are an integrated film making it possible to detect, after the integrated film is bonded to a semiconductor wafer, a notch in this wafer; and others. An aspect of the invention relates to an integrated film including a dicing tape including a substrate and a pressure-sensitive adhesive layer disposed on the substrate; and a rear surface-protective film disposed on the pressure-sensitive adhesive layer. This rear surface-protective film has a total light transmittance of 3% or more at a wavelength of 555 nm. Another aspect of the invention relates to an integrated film having a total light transmittance of 3% or more at a wavelength of 555 nm.

### BACKGROUND OF THE INVENTION

1. Field of the Invention

The present invention relates to an integrated film, a film, a method for producing a semiconductor device, and a method for producing a chip.

2. Description of the Related Art

In recent years, a flip chip type semiconductor device has widely been used, in which semiconductor elements such as semiconductor chips are mounted on a substrate by flip chip bonding. In the flip chip type semiconductor device, a rear surface-protective film may be provided onto the rear surface of the semiconductor elements to prevent a damage of the semiconductor elements, and others. The rear surface-protective film is usually colored to make a mark printed thereon by a laser (hereinafter, the mark will be referred to as the “laser mark”) perceptible (see, for example, Patent Document 1).

An integrated film is known in which a rear surface-protective film is combined with a dicing tape. The integrated film has the dicing tape and the rear surface-protective film disposed on the dicing tape. A method for producing a semiconductor device using the integrated film may have a step of bonding the rear surface-protective film of the integrated film to a semiconductor wafer; and then die-dividing the resultant. The rear surface-protective film of the integrated film is larger than the semiconductor wafer when viewed in plan.

### PRIOR ART DOCUMENT

### Patent Document

Patent Document 1: Japanese Patent No. 4762959

Since the rear surface-protective film of the integrated film is larger than the semiconductor wafer and is further colored, it is difficult to detect a notch in the semiconductor wafer after the rear surface-protective film and the semiconductor wafer are bonded to each other.

### SUMMARY OF THE INVENTION

An object of a first aspect of the present invention is to provide an integrated film and a film each making it possible to detect, after the integrated film and a semiconductor wafer are bonded to each other, a notch in the semiconductor wafer. Another object of the first aspect of the invention is to provide a method for producing a semiconductor device and a method for producing a chip, these methods each making it possible to detect, after an integrated film and a semiconductor wafer are bonded to each other, a notch in the semiconductor wafer.

An object of a second aspect of the present invention is to provide an integrated film and a film each making it possible to detect, after the integrated film and a semiconductor wafer are bonded to each other, a notch in the semiconductor wafer. Another object of the second aspect of the invention is to provide a method for producing a semiconductor device and a method for producing a chip, these methods each making it possible to detect, after an integrated film and a semiconductor wafer are bonded to each other, a notch in the semiconductor wafer.

In order to achieve the above-mentioned objects, the inventors have made eager investigations to think out a technique of making a rear surface-protective film of an integrated film smaller than a semiconductor wafer, thereby preventing a notch in the wafer from being concealed. However, the inventors' investigations have made the following evident: it is difficult to match the position of the integrated film with that of a dicing ring concurrently with matching the position of the rear surface-protective film with that of the semiconductor wafer. Thereafter, the inventors have found out that after an integrated film and a semiconductor wafer are bonded to each other, a notch in the semiconductor wafer can be detected by heightening the total light transmittance of a rear surface-protective film of the integrated film at a wavelength of 555 nm. Thus, the first aspect of the present invention has been achieved.

The first aspect of the present invention relates to an integrated film. The integrated film includes a dicing tape including a substrate and a pressure-sensitive adhesive layer disposed on the substrate, and a rear surface-protective film for protecting a rear surface of a semiconductor element. The rear surface-protective film is disposed on the pressure-sensitive adhesive layer. The rear surface-protective film has a total light transmittance of 3% or more at a wavelength of 555 nm. The total light transmittance of 3% or more makes it possible to detect, after the integrated film is bonded to a semiconductor wafer, a notch in the semiconductor wafer. The semiconductor element is preferably a flip chip.

The first aspect of the present invention also relates to a film including a separator, and the integrated film disposed on the separator.

The first aspect of the present invention also relates to a method for producing a semiconductor device, the method including the steps of providing the integrated film; and bonding the integrated film and a semiconductor wafer to each other. After the step of bonding the integrated film and the semiconductor wafer to each other, this method for producing a semiconductor device may further include a step of making a print on the rear surface-protective film of the integrated film by a laser. The step of making the print on the rear surface-protective film includes a step of detecting a notch in the semiconductor wafer contacting the rear surface-protective film.

The first aspect of the present invention also relates to a method for producing a chip including a semiconductor element and a protective film disposed on a rear surface of the semiconductor element. The method for producing a chip includes a step of providing the integrated film; and a step of bonding the integrated film and a semiconductor wafer to each other. After the step of bonding the integrated film and the semiconductor wafer to each other, this method for producing a chip may further include a step of making a print on the rear surface-protective film of the integrated film by a laser. The step of making the print on the rear surface-protective film includes a step of detecting a notch in the semiconductor wafer contacting the rear surface-protective film.

The inventors have found out that after an integrated film and a semiconductor wafer are bonded to each other, a notch in the semiconductor wafer can be detected by heightening the total light transmittance of the integrated film at a wavelength of 555 nm. Thus, the second aspect of the present invention has been achieved.

The second aspect of the present invention relates to an integrated film having a total light transmittance of 3% or more at a wavelength of 555 nm. The total light transmittance of 3% or more makes it possible to detect, after the integrated film is bonded to a semiconductor wafer, a notch in the semiconductor wafer. The integrated film includes a dicing tape including a substrate and a pressure-sensitive adhesive layer disposed on the substrate, and a rear surface-protective film for protecting a rear surface of a semiconductor element. The rear surface-protective film is disposed on the pressure-sensitive adhesive layer. The semiconductor element is preferably a flip chip.

The second aspect of the present invention also relates to a film including a separator, and the integrated film disposed on the separator.

The second aspect of the present invention also relates to a method for producing a semiconductor device, the method including the steps of providing the integrated film; and bonding the integrated film and a semiconductor wafer to each other. After the step of bonding the integrated film and the semiconductor wafer to each other, this method for producing a semiconductor device may further include a step of making a print on the rear surface-protective film of the integrated film by a laser. The step of making the print on the rear surface-protective film includes a step of detecting a notch in the semiconductor wafer contacting the integrated film.

The second aspect of the present invention also relates to a method for producing a chip including a semiconductor element and a protective film disposed on a rear surface of the semiconductor element. This method for producing a chip includes a step of providing the integrated film; and a step of bonding the integrated film and a semiconductor wafer to each other. After the step of bonding the integrated film and the semiconductor wafer to each other, the method for producing a chip may further include a step of making a print on the rear surface-protective film of the integrated film by a laser. The step of making the print on the rear surface-protective film includes a step of detecting a notch in the semiconductor wafer contacting the integrated film.

### BRIEF DESCRIPTION OF THE DRAWINGS

FIG. 1 is a schematic plan view of a film;

FIG. 2 is a schematic sectional view of apart of the film;

FIG. 3 is a schematic sectional view of a process for producing a semiconductor device;

FIG. 4 is a schematic plan view of a semiconductor wafer;

FIG. 5 is a schematic sectional view of the process for producing a semiconductor device;

FIG. 6 is a schematic sectional view of the process for producing a semiconductor device; and

FIG. 7 is a schematic sectional view of a part of a film in Modified Example 1.

### DETAILED DESCRIPTION OF THE PREFERRED EMBODIMENTS

Hereinafter, the present invention will be described in detail by way of embodiments thereof. However, the invention is not limited only to these embodiments.

### Embodiment 1

### Film 1

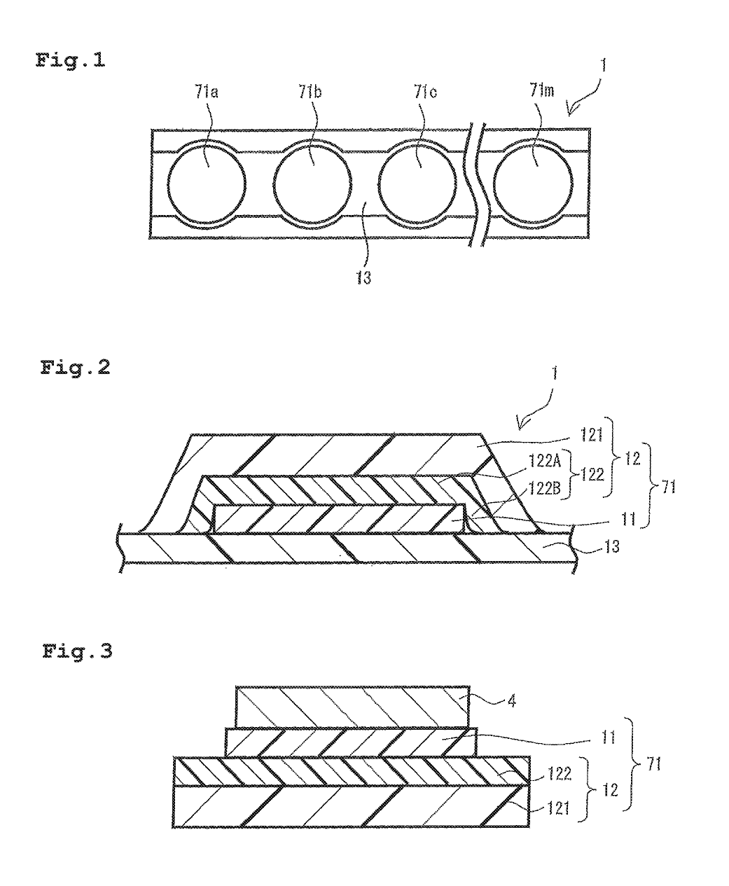

As illustrated in FIGS. 1 and 2, a film 1 includes a separator 13 and a rear surface-protective film 11 disposed on the separator 13. More specifically, the film 1 includes the separator 13, and integrated films 71a, 71b, 71c, . . . 71m (hereinafter called an “integrated film 71” generically). The distance between the integrated films 71a and 71b, the distance between the integrated films 71b and 71c, . . . . , and the distance between the integrated films 71l and 71m are equal to each other. The film 1 may be made into a roll form.

### (Integrated Film 71)

The integrated film 71 includes a dicing tape 12 and the rear surface-protective film 11 disposed on the dicing tape 12. The dicing tape 12 includes a substrate 121 and a pressure-sensitive adhesive layer 122 disposed on the substrate 121. The pressure-sensitive adhesive layer 122 includes a contacting region 122A contacting the rear surface-protective film 11. The pressure-sensitive adhesive layer 122 further includes a peripheral region 122B disposed in the periphery of the contacting region 122A. The contacting region 122A is cured by radial rays. In the meantime, the peripheral region 122B has a property of being cured by radial rays. The radial rays are preferably ultraviolet rays.

About the substrate 121, both surfaces thereof can be defined as a first main surface that contacts the pressure-sensitive adhesive layer 122, and a second main surface opposed to the first main surface. About the rear surface-protective film 11, both surfaces thereof can be defined as a first surface that contacts the pressure-sensitive adhesive layer 122, and a second surface opposed to the first surface. The second surface contacts the separator 13.

The total light transmittance of the integrated film 71 at a wavelength of 555 nm is 3% or more, preferably 5% or more, more preferably 7% or more. When the transmittance is 3% or more, a notch in a semiconductor wafer can be detected after the integrated film 71 is bonded to the semiconductor wafer. The upper limit of the total light transmittance of the integrated film 71 at the wavelength of 555 nm is, for example, 50%, 30% or 20%.

The thickness of the integrated film 71 is preferably 8 μm or more, more preferably 20 μm or more, even more preferably 31 μm or more, in particular preferably 47 μm or more. In the meantime, the thickness of the integrated film 71 is preferably 1500 μm or less, more preferably 850 μm or less, even more preferably 500 μm or less, in particular preferably 330 μm or less.

### (Rear Surface-Protective Film 11)

The total light transmittance of the rear surface-protective film 11 at a wavelength of 555 nm is 3% or more, preferably 5% or more, more preferably 7% or more. When the transmittance is 3% or more, a notch in a semiconductor wafer can be detected after the rear surface-protective film 11 is bonded to the semiconductor wafer. The upper limit of the total light transmittance of the rear surface-protective film 11 at the wavelength of 555 nm is, for example, 50%, 30% or 20%

The total light transmittance at the wavelength of 555 nm is controllable by the thickness of the rear surface-protective film 11, the kind of a colorant, and some other. For example, the reduction of the thickness of the rear surface-protective film 11 or the use of a dye as the colorant makes it possible to heighten the total light transmittance at the wavelength of 555 nm.

The rear surface-protective film 11 is preferably colored. When the rear surface-protective film 11 is colored, a laser mark on the rear surface-protective film 11 is easily perceptible. The rear surface-protective film 11 preferably has a deep color such as black, blue or red color. Black color is particularly preferred.

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de l'Eclairage (CIE) in 1976, and means a color space that is called a CIE1976 (L*a*b*) color system. The L*a*b* color system is provided in JIS Z 8729 in the Japanese Industrial Standards.

The rear surface-protective film 11 is usually in an uncured state. The uncured state also includes a semi-cured state. The rear surface-protective film 11 is preferably in a semi-cured state.

When the rear surface-protective film 11 is allowed to stand still in an atmosphere of 85° C. and 85% RH for 168 hours, the moisture absorption coefficient thereof is preferably 1% by weight or less, more preferably 0.8% by weight or less. When the coefficient is 1% by weight or less, this film can be improved in laser markability. The moisture absorption coefficient is controllable by the content of an inorganic filler in the film, and others.

A method for measuring the moisture absorption coefficient of the rear surface-protective film 11 is as follows: the rear surface-protective film 11 is allowed to stand still in a thermostat of 85° C. and 85% RH for 168 hours; and the moisture absorption coefficient is gained from the film weight loss before and after the standing-still.

By curing the rear surface-protective film 11, a cured product is obtained, and the moisture absorption coefficient of this cured product is preferably 1% by weight or less, more preferably 0.8% by weight or less when this product is allowed to stand still in an atmosphere of 85° C. and 85% RH for 168 hours. When the moisture absorption coefficient is 1% by weight or less, the rear surface-protective film can be improved in laser markability. The moisture absorption coefficient is controllable by the content of the inorganic filler in the film, and others.

A method for measuring the moisture absorption coefficient of the cured product is as follows: the cured product is allowed to stand still in a thermostat of 85° C. and 85% RH for 168 hours; and the moisture absorption coefficient is gained from the product weight loss before and after the standing-still.

The fraction of a gel in the rear surface-protective film 11 is preferably 50% or more, more preferably 70% or more, even more preferably 90% or more, this gel being obtained by subjecting the film 11 to extraction with ethanol. When the gel fraction is 50% or more, the rear surface-protective film 11 can be prevented from sticking onto a tool or some other in a semiconductor producing process.

The gel fraction in the rear surface-protective film 11 is controllable by the kind of a resin component, the content thereof, the kind of a crosslinking agent or the content thereof in the film, the heating temperature, the heating period, and others.

The tensile storage elastic modulus of the rear surface-protective film 11 at 23° C. is preferably 0.5 GPa or more, more preferably 0.75 GPa or more, even more preferably 1 GPa or more when the film is in an uncured state. When the tensile storage elastic modulus is 1 GPa or more, the rear surface-protective film 11 can be prevented from adhering onto a carrier tape. The upper limit of the tensile storage elastic modulus at 23° C. is, for example, 50 GPa. The tensile storage elastic modulus at 23° C. is controllable by the kind of the resin component, the content thereof, the kind of the filler or the content thereof in the film, and others.

The rear surface-protective film 11 may be electroconductive or non-electroconductive.

The adhering strength (at 23° C., a peeling angle of 180° and a peeling rate of 300 mm/minute) of the rear surface-protective film 11 to a semiconductor wafer is preferably 1 N/10 mm width or more, more preferably 2 N/10 mm width or more, even more preferably 4 N/10 mm width or more. In the meantime, this adhering strength is preferably 10 N/10 mm width or less. When the adhering strength is 1 N/10 mm width or more, the rear surface-protective film 11 can adhere to a semiconductor wafer or a semiconductor element with excellent adhesiveness so that this film 11 can also be prevented from undergoing a partial peeling-up and other inconveniences. When the semiconductor wafer is diced, its chips can also be prevented from being scattered. The adhering strength of the rear surface-protective film 11 to a semiconductor wafer is a value measured, for example, as follows: a pressure-sensitive adhesive tape (trade name: “BT315”, manufactured by Nitto Denko Corporation) is bonded to one surface of the rear surface-protective film 11 to reinforce the rear surface. Thereafter, a semiconductor wafer having a thickness of 0.6 mm is bonded to the front surface of the rear surface-reinforced rear surface-protective film 11, which has a length of 150 mm and a width of 10 mm, by a thermal laminating method at 50° C. in which a roller of 2 kg weight is moved forward and backward one time onto the film. Thereafter, the resultant is allowed to stand still on a hot plate (50° C.) for 2 minutes, and then to stand still at room temperature (at about 23° C.) for 20 minutes. After the standing-still, a peeling tester (trade name: “AUTOGRAPHAGS-J”, manufactured by Shimadzu Corporation) is used to peel off the rear surface-reinforced rear surface-protective film 11 at a temperature of 23° C., a peeling angle of 180° and a tensile rate of 300 mm/minute. The adhering strength of the rear surface-protective film 11 to the semiconductor wafer is a value (unit: N/10 mm width) measured for the peel of the rear surface-protective film 11 and the semiconductor wafer from each other at the interface therebetween at this time.

The thickness of the rear surface-protective film 11 is preferably 2 μm or more, more preferably 4 μm or more, even more preferably 6 μm or more, in particular preferably 10 μm or more. In the meantime, the thickness of the rear surface-protective film 11 is preferably 200 μm or less, more preferably 160 μm or less, more preferably 100 μm or less, even more preferably 80 μm or less, in particular preferably 50 μm or less.

The rear surface-protective film 11 preferably contains a colorant. The colorant may be, for example, a dye or a pigment.

The dye is preferably a deep color dye. Examples of the deep color dye may include black dyes, blue dyes, and red dyes. Black dyes are particularly preferred. The pigment is preferably a deep color pigment. Examples of the deep color pigment may include black pigments, blue pigments, and red pigments. Black pigments are particularly preferred. Such colorants may be used singly or in any combination of two or more thereof.

The content of the colorant in the rear surface-protective film 11 is preferably 0.5% by weight or more, more preferably 1% by weight or more, even more preferably 2% by weight or more. The content of the colorant in the rear surface-protective film 11 is preferably 10% by weight or less, more preferably 8% by weight or less, even more preferably 5% by weight or less.

The rear surface-protective film 11 preferably contains a thermoplastic resin.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET (polyethylene terephthalate) and PBT (polybutylene terephthalate), a polyamideimide resin, and a fluororesin. The thermoplastic resins can be used alone or two types or more can be used together. Among these thermoplastic resins, an acrylic resin and a phenoxy resin are preferable.

The acrylic resin is not especially limited, and examples thereof include a polymer having one type or two types or more of acrylates or methacrylates having a linear or branched alkyl group having 30 or less carbon atoms (preferably 4 to 18 carbon atoms, further preferably 6 to 10 carbon atoms, and especially preferably 8 or 9 carbon atoms) as a component. That is, the acrylic resin of the present invention has a broad meaning and also includes a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers that can form the above-described acrylic resin (monomers other than an alkylester of acrylic acid or methacrylic acid having an alkyl group having 30 or less carbon atoms) are not especially limited. Examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate. (Meth)acrylate refers to an acrylate and/or a methacrylate, and every “(meth)” in the present invention has the same meaning.

The content of the thermoplastic resin in the rear surface-protective film 11 is preferably 10% by weight or more, more preferably 30% by weight or more. The content of the thermoplastic resin in the rear surface-protective film 11 is preferably 90% by weight or less, more preferably 70% by weight or less.

The rear surface-protective film 11 may contain a thermosetting resin.

Examples of the thermosetting resin include an epoxy resin, a phenolic resin, an amino resin, an unsaturated polyester resin, a polyurethane resin, a silicone resin, and a thermosetting polyimide resin. The thermosetting resins can be used alone or two types or more can be used together. An epoxy resin having a small amount of ionic impurities that erode the semiconductor element is especially suitable as the thermosetting resin. Further, a phenolic resin can be suitably used as a curing agent for the epoxy resin.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Out of these examples, particularly preferred are novolak type epoxy resin, biphenyl type epoxy resin, trishydroxyphenylmethane type epoxy resin, and tetraphenylolethane type epoxy resin. This is because these epoxy resins are rich in reactivity with phenolic resin as the curing agent, and are excellent in heat resistance and the like.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2

### EQUIVALENTS

The content of the thermosetting resin in the rear surface-protective film 11 is preferably 2% by weight or more, more preferably 5% by weight or more. The content of the thermosetting resin in the rear surface-protective film 11 is preferably 40% by weight or less, more preferably 20% by weight or less.

The rear surface-protective film 11 may contain a thermosetting promoting catalyst for the epoxy resin and the phenolic resin. The thermosetting promoting catalyst is not particularly limited, and may be appropriately selected from known thermosetting promoting catalysts. The thermosetting promoting catalysts may be used singly or in any combination of two or more thereof. The thermosetting promoting catalysts may be, for example, amine type, phosphorus-containing type, imidazole type, boron-containing type, and phosphorus-boron-containing type thermosetting promoting catalysts.

In order to crosslink the rear surface-protective film 11 to some degree in advance, it is preferred in the production of the rear surface-protective film 11 to add the following as a crosslinking agent to the rear surface-protective film 11: a polyfunctional compound reactive with, for example, a functional group of a molecular chain terminal of a polymer. This makes it possible to improve the film 11 in adhesive property at high temperature and heat resistance.

The crosslinking agent is not especially limited, and a known crosslinking agent can be used. Specific examples thereof include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. An isocyanate crosslinking agent and an epoxy crosslinking agent are preferable. The crosslinking agents can be used alone or two type or more can be used together.

Examples of the isocyanate crosslinking agent include lower aliphatic polyisocyanates such as 1,2-ethylene diisocyanate, 1,4-butylene isocyanate, and 1,6-hexamethylene diisocyanate; alicyclicpolyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethanediisocyanate, andxylylenediisiocyanate. A trimethylolpropane/tolylene diisocyanate trimer adduct (tradename: Coronate L manufactured by Nippon Polyurethane Industry Co., Ltd.) and a trimethylolpropane/hexamethylene diisocyanate trimer adduct (tradename: Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerythritol polyglycidylether, polyglyserol polyglycidylether, sorbitan polyglycidylether, trimethylolpropane polyglycidylether, diglycidyl adipate, diglycidyl o-phthalate, triglycidyl-tris(2-hydroxyethyl)isocyanurate, resorcin diglycidylether, bisphenol-s-diglycidyl ether, and an epoxy resin having two or more epoxy groups in the molecule.

In the present invention, it is possible to perform a crosslinking treatment by irradiation with an electron beam, an ultraviolet ray, or the like in place of using the crosslinking agent or together with a crosslinking agent.

The rear surface-protective film 11 may contain a filler. When the rear surface-protective film 11 contains the filler, the film 11 can be adjusted in elastic modulus and others.

The filler may be an inorganic filler or an organic filler, and is preferably an inorganic filler. The inorganic filler may be powder of an inorganic substance that may be of various type. Examples of the substance include ceramics such as silica, clay, plaster, calcium carbonate, barium sulfate, alumina, beryllium oxide, silicon carbide and silicon nitride; metals such as aluminum, copper, silver, gold, nickel, chromium, lead, tin, zinc, palladium and solder, and any alloy composed of two or more of these metals; and carbon. Such fillers may be used singly or in any combination of two or more thereof. The filler is preferably silica, in particular preferably synthetic silica. The average particle diameter of the inorganic filler ranges preferably from 0.1 μm to 80 μm. The average particle diameter of the inorganic filler is measurable, using, for example, a laser diffraction type particle size distribution measuring instrument.

The content of the filler in the rear surface-protective film 11 is preferably 10% by weight or more, more preferably 20% by weight or more. The content of the filler in the rear surface-protective film 11 is preferably 70% by weight or less, more preferably 50% by weight or less.

The rear surface-protective film 11 may appropriately contain any other additive. Examples of the other additive include a flame retardant, a silane coupling agent, an ion trapping agent, an extender, an anti-aging agent, an antioxidant, and a surfactant.

Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

The rear surface-protective film 11 can be yielded by, for example, a method of mixing a thermosetting resin, a thermoplastic resin, a solvent and others with one another to prepare a mixed liquid, applying the mixed liquid onto a peeling paper piece, and drying the resultant workpiece.

### (Dicing Tape 12)

The total light transmittance of the dicing tape 12 at a wavelength of 555 nm is preferably 3% or more, more preferably 10% or more, even more preferably 20% or more. When the transmittance is 10% or more, a notch in a semiconductor wafer can be detected after the integrated film 71 is bonded to the semiconductor wafer. The upper limit of the total light transmittance of the dicing tape 12 at the wavelength of 555 nm is, for example, 95% or 90%

The total light transmittance of the dicing tape 12 at the wavelength of 555 nm is controllable by the surface irregularities of the second main surface of the substrate 121, or the kind of a colorant.

The substrate 121 preferably has radial ray transmissivity. The substrate 121 more preferably has ultraviolet ray transmissivity. Examples of the substrate 121 include appropriate thin materials including paper substrates such as paper; fiber substrates such as cloth, unwoven cloth, felt, and net; metal substrates such as a metal foil and a metal plate; plastic substrates such as a plastic film and sheet; rubber substrates such as a rubber sheet; foams such as a foamed sheet, and laminated bodies of these (especially laminated bodies of a plastic base and other bases and laminated bodies of plastic films or sheets). A plastic substrate such as a plastic film or sheet can be preferably used as the substrate 121. Examples of the material of such a plastic base include olefin resins such as polyethylene (PE), polypropylene (PP), and an ethylene-propylene copolymer; copolymers having ethylene as a monomer component such as a ethylene vinyl acetate copolymer (EVA), an ionomer resin, a ethylene-(meth)acrylate copolymer, and an ethylene-(meth)acrylate (random, alternating) copolymer; polyesters such as polyethylene terephthalate (PET), polyethylene naphthalate (PEN), and polybutylene terephthalate (PBT); an acrylic resin; polyvinyl chloride (PVC); polyurethane; polycarbonate; polyphenylene sulfide (PPS); amide resins such as polyamide (nylon) and fully aromatic polyamide (aramid); polyether ether ketone (PEEK); polyimide; polyetherimide; polyvinylidene chloride; ABS (acrylonitrile-butadiene-styrene copolymer); a cellulose resin; a silicone resin; and a fluororesin.

The substrate 121 may be used in the state of being undrawn, or may be used in the state of being, as needed, monoaxially or biaxially drawn. When a thermal shrinkage characteristic is given to the substrate 121 by, for example, drawing, the thermal shrinkage of the substrate 121 causes a fall in the contact area between the pressure-sensitive adhesive layer 122 and the rear surface-protective film 11 to make the collection of a semiconductor device easy.

A known surface treatment such as a chemical or physical treatment such as a chromate treatment, ozone exposure, flame exposure, high voltage electric exposure, and an ionized ultraviolet treatment, and a coating treatment by an undercoating agent can be performed on the surface of the substrate 121 in order to improve adhesiveness, holding properties, etc. with the adjacent layer.

The same type or different types can be appropriately selected and used as the substrate 121, and several types can be blended and used as necessary. A vapor deposited layer of a conductive substance having a thickness of about 30 to 500 Å consisting of metals, alloys, and oxides of these can be provided on the substrate 121 to give an antistatic function to the substrate 121. The substrate 121 may be a single layer or a multilayer consisting of two types or more layers.

The thickness of the substrate 121 (the total thickness when the substrate 121 is a laminated body) is not particularly limited, and may be appropriately selected in accordance with a desired strength or flexibility thereof, a use purpose thereof, and others. The thickness is, for example, a thickness generally of about 1000 μm or less (which ranges, for example, from 1 μm to 1000 μm), and is preferably from about 10 μm to 500 μm, more preferably from about 20 μm to 300 μm, in particular preferably from about 30 μm to 200 μm. However, the thickness is not limited to these ranges.

The substrate 121 may contain various additives (such as a colorant, a filler, a plasticizer, an anti-aging agent, an antioxidant, a surfactant, and a flame retardant).

The pressure-sensitive adhesive layer 122 is formed with a pressure-sensitive adhesive, and has adherability. The pressure-sensitive adhesive is not especially limited, and can be appropriately selected among known pressure-sensitive adhesives. Specifically, known pressure-sensitive adhesives (refer to Japanese Patent Application Laid-Open Nos. 56-61468, 61-174857, 63-17981, and 56-13040, for example) such as a pressure-sensitive adhesive having the above-described characteristics can be appropriately selected from an acrylic pressure-sensitive adhesive, a rubber pressure-sensitive adhesive, a vinylalkylether pressure-sensitive adhesive, a silicone pressure-sensitive adhesive, a polyester pressure-sensitive adhesive, a polyamide pressure-sensitive adhesive, a urethane pressure-sensitive adhesive, a fluorine pressure-sensitive adhesive, a styrene-diene block copolymer pressure-sensitive adhesive, and a creep property improved pressure-sensitive adhesive in which a hot-melt resin having a melting point of about 200° C. or less is compounded in these pressure-sensitive adhesives. A radiation curing type pressure-sensitive adhesive (or an energy ray curing type pressure-sensitive adhesive) and a thermally expandable pressure-sensitive adhesive can also be used as the pressure-sensitive adhesive. The pressure-sensitive adhesives can be used alone or two types or more can be used together.

An acrylic pressure-sensitive adhesive and a rubber pressure-sensitive adhesive can be suitably used as the pressure-sensitive adhesive, and especially an acrylic pressure-sensitive adhesive is suitable. An example of the acrylic pressure-sensitive adhesive is an acrylic pressure-sensitive adhesive having an acrylic polymer, in which one type or two types or more of alkyl (meth)acrylates are used as a monomer component, as a base polymer.

Examples of alkyl (meth)acrylates in the acrylic pressure-sensitive adhesive include methyl (meth)acrylate, ethyl (meth)acrylate, propyl (meth)acrylate, isopropyl (meth)acrylate, butyl(meth)acrylate, isobutyl(meth)acrylate, s-butyl (meth)acrylate, t-butyl (meth)acrylate, pentyl (meth)acrylate, hexyl (meth)acrylate, heptyl (meth)acrylate, octyl (meth)acrylate, 2-ethylhexyl (meth)acrylate, isooctyl (meth)acrylate, nonyl(meth)acrylate, isononyl(meth)acrylate, decyl (meth)acrylate, isodecyl (meth)acrylate, undecyl (met)acrylate, dodecyl(meth)acrylate, tridecyl(meth)acrylate, tetradecyl (meth)acrylate, pentadecyl (meth)acrylate, hexadecyl(meth)acrylate, heptadecyl(meth)acrylate, octadecyl (meth)acrylate, nonadecyl (meth)acrylate, and eicosyl (meth)acrylate. Alkyl (meth)acrylates having an alkyl group of 4 to 18 carbon atoms is suitable. The alkyl group of alkyl (meth)acrylates may be any of linear or branched chain.

The acrylic polymer may contain units that correspond to other monomer components that is copolymerizable with alkyl (meth)acrylates described above (copolymerizable monomer component) for reforming cohesive strength, heat resistance, and crosslinking property, as necessary. Examples of such copolymerizable monomer components include carboxyl group-containing monomers such as (meth)acrylic acid (acrylic acid, methacrylic acid), carboxyethyl acrylate, carboxypentyl acrylate, itaconic acid, maleic acid, fumaric acid, and crotonic acid; acid anhydride group-containing monomers such as maleic anhydride and itaconic anhydride; hydroxyl group-containing monomers such as hydroxyethyl (meth)acrylate, hydroxypropyl (meth)acrylate, hydroxybutyl (meth)acrylate, hydroxyhexyl (meth)acrylate, hydroxyoctyl (meth)acrylate, hydroxydecyl (meth)acrylate, hydroxylauryl (meth)acrylate, and (4-hydroxymethylcyclohexyl)methyl methacrylate; sulfonate group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphate group-containing monomers such as 2-hydroxyethylacryloylphosphate; (N-substituted) amide monomers such as (meth)acrylamide, N,N-dimethyl(meth)acrylamide, N-butyl(meth)acrylamide, N-methylol(meth)acrylamide, and N-methylolpropane(meth)acrylamide; aminoalkyl (meth)acrylate monomers such as aminoethyl (meth)acrylate, N,N-dimethlaminoethyl (meth)acrylate, and t-butylaminoethyl (meth)acrylate; alkoxyalkyl (meth)acrylate monomers such as methoxyethyl (meth)acrylate and ethoxyethyl (meth)acrylate; cyanoacrylate monomers such as acrylonitrile and methacrylonitrile; epoxy group-containing acrylic monomers such as glycidyl(meth)acrylate; styrene monomers such as styrene and α-methylstyrene; vinylester monomers such as vinyl acetate andvinylpropionate; olefinmonomers such as isoprene, butadiene, and isobutylene; vinylether monomers such as vinylether; nitrogen-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinyl imidazole, vinyloxazole, vinylmorpholine, N-vinylcarboxylic acid amides, and N-vinylcaprolactam; maleimide monomers such as N-cyclohexylmaleimide, N-isopropylmaleimide, N-laurylmaleimide, and N-phenylmaleimide; itaconimide monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide monomers such as N-(meth)acryloyloxymethylene succinimide, N-(meth)acryloyl-6-oxyhexamethylene succinimide, and N-(meth)acryloyl-8-oxyoctamethylene succinimide; glycol acrylester monomers such as polyethylene glycol (meth)acrylate, polypropylene glycol (meth)acrylate, metoxyethylene glycol (meth)acrylate, and metoxypolypropylene glycol (meth)acrylate; acrylate monomers having a heterocyclic ring, a halogen atom, a silicon atom, and the like such as tetrahydrofurfuryl (meth)acrylate, fluorine (meth)acrylate, and silicone (meth)acrylate; and polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxyacrylate, polyesteracrylate, urethaneacrylate, divinylbenzene, butyl di(meth)acrylate, and hexyl di(meth)acrylate. One type or two types or more of these copolymerizable monomer components can be used.

When a radiation curing type pressure-sensitive adhesive (or an energy ray curing type pressure-sensitive adhesive) is used as the pressure-sensitive adhesive, examples of the radiation curing type pressure-sensitive adhesive (composition) include an internal radiation curing type pressure-sensitive adhesive having a polymer with a radical reactive carbon-carbon double bond in the polymer side chain, the main chain, or the ends of the main chain as a base polymer and a radiation curing type pressure-sensitive adhesive in which ultraviolet-ray curing-type monomer component and oligomer component are compounded in the pressure-sensitive adhesive. When a thermally expandable pressure-sensitive adhesive is used as the pressure-sensitive adhesive, examples thereof include a thermally expandable pressure-sensitive adhesive containing a pressure-sensitive adhesive and a foaming agent (especially, a thermally expandable microsphere).

The pressure-sensitive adhesive layer 122 may contain various additives (such as a tackifier resin, a colorant, a thickener, an extender, a filler, a plasticizer, an anti-aging agent, an antioxidant, a surfactant, and a crosslinking agent).

The pressure-sensitive adhesive layer 122 can be formed by, for example, a usual method of mixing a pressure-sensitive adhesive with a solvent, other additives, and so on optionally, and forming the mixture into a layer in a sheet form. Specifically, the pressure-sensitive adhesive layer 122 can be formed by, for example, a method of applying a mixture containing a pressure-sensitive adhesive and optionally a solvent and other additives onto the substrate 121, or a method of applying such a mixture onto an appropriate separator (such as a peeling paper piece) to form the pressure-sensitive adhesive layer 122, and transferring (transcribing) this layer onto the substrate 121.

The thickness of the pressure-sensitive adhesive layer 122 is not particularly limited, and is, for example, from about 5 μm to 300 μm, preferably from about 5 μm to 200 μm, more preferably from about 5 μm to 100 μm, in particular preferably from about 7 μm to 50 μm. When the thickness of the pressure-sensitive adhesive layer 122 is in the range, this layer can exhibit appropriate adhesive strength. The pressure-sensitive adhesive layer 122 may have a monolayered or multilayered structure.

### (Separator 13)

The separator 13 may be, for example, a polyethylene terephthalate (PET) film. The separator 13 is preferably a separator subjected to release treatment. The thickness of the separator 13 may be appropriately set.

### (Method for Producing Semiconductor Device and Method for Producing Chip)

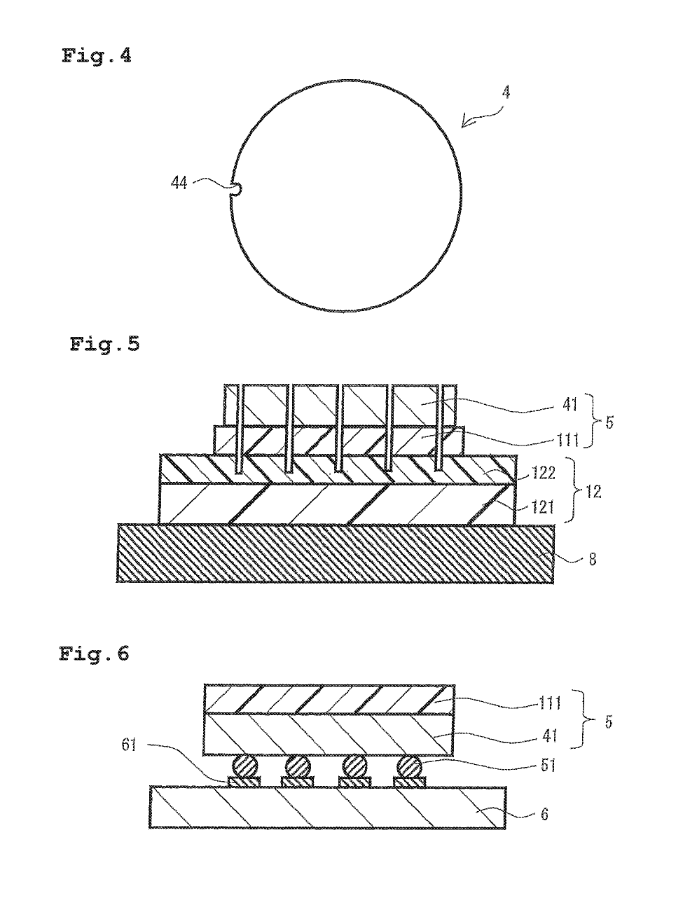

As illustrated in FIG. 3, the integrated film 71 is bonded to a semiconductor wafer 4. Specifically, the separator 13 is peeled off from the integrated film 71, and the integrated film 71 is bonded to the semiconductor wafer 4. This allows the rear surface-protective film 11 to be provided on the rear surface of the semiconductor wafer 4. The method for the bonding is not particularly limited, but is preferably pressure bonding. The pressure bonding is usually performed by pressing with a pressing member such as a pressure bonding roller.

As illustrated in FIG. 4, a notch 44 is provided in the semiconductor wafer 4. About the semiconductor wafer 4, both surfaces thereof can be defined as a circuit surface and a rear surface opposed to the circuit surface (the rear surface may also be called, for example, non-circuit surface or non-electrode formed surface). The semiconductor wafer 4 is preferably a silicon wafer.

Through a detecting sensor for detecting the notch 44, the notch 44 in the semiconductor wafer 4 contacting the integrated film 71 can be detected. This makes it possible to produce positional information on the notch 44 provided in the semiconductor wafer 4, so that a region of the rear surface-protective film 11 where a laser is to be applied can be specified. Examples of the detecting sensor include microscopes, transmission type sensors, and reflection type sensors.

A print can be made on the rear surface-protective film 11 by a laser. In the printing by the laser, a known laser marking device is usable. The laser is, for example, a gas laser, a solid laser or a liquid laser. Specifically, the gas laser is not particularly limited, and may be a known gas laser. The gas laser is preferably carbon dioxide gas laser (CO₂ laser), or an excimer laser (such as ArF laser, KrF laser, XeCl laser or XeF laser). The solid laser is not particularly limited, and may be a known solid laser. The solid laser is preferably a YAG laser (such as Nd:YAG laser), or YVO₄ laser.

As illustrated in FIG. 5, the semiconductor wafer 4 is diced. In this way, protected chips 5 are formed. The protected chips 5 each include a semiconductor element 41 and a protective film 111 disposed on the rear surface of the semiconductor element 41. About the semiconductor element 41, both surfaces thereof can be defined as a circuit surface (the surface may also be called, for example, front surface, circuit pattern formed surface, or electrode formed surface), and a rear surface opposed to the circuit surface. The dicing is attained, for example, from the circuit surface side of the semiconductor wafer 4 in a usual way in the state that the dicing tape 12 is vacuum-adsorbed onto an adsorbing stand 8. In the present step, for example, a cutting way called full cut may be adopted, in which cuts are made down to the integrated film 71. A dicing machine used in the present step is not particularly limited, and may be any dicing machine known in the prior art.

Next, the protected chips 5 are peeled off from the pressure-sensitive adhesive layer 122 of the dicing tape 12. In other words, the protected chips 5 are picked up. The method for the picking-up is not particularly limited. Various method known in the prior art may be used. The method is, for example, a method of picking up the protected chips 5 with a needle, and then picking up the pricked protected chips 5 by a picking-up device.

As illustrated in FIG. 6, any one of the protected chips 5 is fixed onto an adherend 6 in a flip chip bonding manner (or in a flip chip mounting manner). Specifically, in the state that the circuit surface of the semiconductor element 41 faces the adherend 6, the protected chip 5 is fixed onto the adherend 6. For example, while bumps 51 provided on the circuit surface of the semiconductor element 41 are brought into contact with electroconductive members 61 (such as solders) for joint that cover connecting pads of the adherend 6 and then are pressed onto the electroconductive members 61, these members 61 are melted to ensure electrical conduction between the semiconductor element 41 and the adherend 6, and fix the protected chip 5 onto the adherend 6 (flip chip bonding step). At this time, gaps are made between the protected chip 5 and the adherend 6. The distance between the gaps is generally from about 30 to 300 μm. After the protected chip 5 is flip-chip-bonded (or flip-chip-connected) to the adherend 6, the facing surfaces of the protected chip 5 and the adherend 6 and the gaps are cleaned, and then a sealant (such as a sealing resin) is filled into the gaps. In this way, the present workpiece can be sealed up.

The adherend 6 may be, for example, a lead frame, or a circuit substrate (wiring circuit board), or some other substrate. The material of such a substrate is not particularly limited. The substrate may be, for example, a ceramic substrate or a plastic substrate. The plastic substrate may be, for example, an epoxy resin substrate, a bismaleimide triazine substrate, or a polyimide substrate.

The material of the bumps and the electroconductive members is not particularly limited. Examples thereof include tin-lead based, tin-silver based, tin-silver-copper based, tin-zinc based and tin-zinc-bismuth based metal materials, and other solder materials (alloys); and gold based metal materials and copper based metal materials.

When the electroconductive members 61 are melted, the temperature at the melting is usually about 260° C. (for example, 250 to 300° C.). When the rear surface-protective film 11 contains an epoxy resin, this film can resist such temperatures.

In the present step, it is preferred to clean the facing surfaces (electrode formed surfaces) of the protected chip 5 and the adherend 6, and the gaps therebetween. A cleaning liquid used for the cleaning is not particularly limited, and may be, for example, an organic cleaning liquid or an aqueous cleaning liquid.

Next, a sealing step is performed to seal the gaps between the protected chip 5 and the adherend 6 flip-chip-bonded to each other. The sealing step is performed using a sealing resin. Sealing conditions at this time are not particularly limited. Usually, by heating at 175° C. for 60 seconds to 90 seconds, the sealing resin is thermally cured. However, in the present invention, the conditions are not limited to the conditions. For example, at 165° C. to 185° C. for several minutes, the resin can be cured. This step makes it possible to thermally cure the protective film 111 completely or substantially completely. Furthermore, even when the protective film 111 is in an uncured state, this film together with the sealant can be thermally cured in this sealing step, so that it is unnecessary to add a new step of thermally curing the protective film 111.

The sealing resin is not particularly limited as far as the resin is a resin having electrically insulating property (insulating resin). The sealing resin is preferably an insulating resin having elasticity. The sealing resin is, for example, a resin composition containing an epoxy resin. The sealing resin made of this epoxy resin-containing resin composition may contain, besides the epoxy resin, for example, a thermosetting resin (such as a phenolic resin) other than any epoxy resin, or a thermoplastic resin as a resin component. The phenolic resin is usable also as a curing agent for the epoxy resin. The form of the sealing resin may be, for example, a film or tablet form.

A semiconductor device (flip-chip-bonded semiconductor device) obtained by the above-mentioned method includes the adherend 6 and the protected chip 5 fixed onto the adherend 6. A print can be made on the protective film 111 of this semiconductor device by a laser. In the printing by the laser, a known laser marking device is usable. The laser is, for example, a gas laser, a solid laser or a liquid laser. Specifically, the gas laser is not particularly limited, and may be a known gas laser. The gas laser is preferably carbon dioxide gas laser (CO₂ laser), or an excimer laser (such as ArF laser, KrF laser, XeCl laser or XeF laser). The solid laser is not particularly limited, and may be a known solid laser. The solid laser is preferably a YAG laser (such as Nd:YAG laser), or YVO₄ laser.

A semiconductor device in which semiconductor elements are mounted in a flip chip bonding manner is thinner and smaller than a semiconductor device in which semiconductor elements are mounted in a die bonding manner. For this reason, the former semiconductor device is appropriately usable for various electric instruments or electronic components, or as a component or member of these instruments or components. Specifically, an electronic instrument in which the flip-chip-bonded semiconductor device is used is, for example, the so-called “portable telephone” or “PHS”, a small-sized computer (such as the so-called “PDA” (portable data assistant), the so-called “laptop computer”, the so-called “net book (trademark)”, or the so-called “wearable computer”), a small-sized electronic instrument to which a “portable telephone” and a computer are integrated, the so-called “digital camera (trademark)”, the so-called “digital video camera”, a small-sized television, a small-sized game machine, a small-sized digital audio player, the so-called “electronic notebook”, the so-called “electronic dictionary”, the so-called electronic instrument terminal for “electronic dictionary”, a small-sized digital-type clock, or any other mobile type electronic instrument (portable electronic instrument). Of course, the electronic instrument may be, for example, an electronic instrument of a type (setup type) other than any mobile type (this instrument being, for example, the so-called “disk top computer”, a thin-type television, an electronic instrument for recording and reproduction (such as a hard disk recorder or a DVD player), a projector, or a micro machine). An electronic component in which the flip-chip-bonded semiconductor device is used, or such a component or member of an electronic instrument or electronic component is, for example, a member of the so-called “CPU”, or a member of a memorizing unit (such as the so-called “memory”, or a hard disk) that may be of various types.

As described above, the method for producing a semiconductor device includes, for example, the step of providing the integrated film 71, and the step of bonding the integrated film 71 and the semiconductor wafer 4 to each other. After the step of bonding the integrated film 71 and the semiconductor wafer 4 to each other, the method for producing a semiconductor device further includes the step of making a print on the rear surface-protective film 11 by a laser. The step of making the print on the rear surface-protective film 11 includes a step of detecting the notch 44 in the semiconductor wafer 4 contacting the rear surface-protective film 11. After the step of making the print on the rear surface-protective film 11, the method for producing a semiconductor device further includes a step of forming the protected chips 5 by dicing. The method for producing a semiconductor device further includes a step of fixing any one of the protected chips 5 to an adherend 6. The step of fixing the protected chip 5 to the adherend 6 is preferably a step of fixing the protected chip 5 onto the adherend 6 by flip chip connection.

As described above, the method for producing the protected chip 5 includes, for example, the step of providing the integrated film 71 and the step of bonding the integrated film 71 and the semiconductor wafer 4 to each other. After the step of bonding the integrated film 71 and the semiconductor wafer 4 to each other, the method for producing the protected chip 5 further includes a step of making a print on the rear surface-protective film 11 by a laser. The step of making the print on the rear surface-protective film 11 includes a step of detecting the notch 44 in the semiconductor wafer 4 contacting the rear surface-protective film 11. After the step of making the print on the rear surface-protective film 11, the method for producing the protected chip 5 further includes the step of forming the protected chips 5 by dicing.

### Modified Example 1

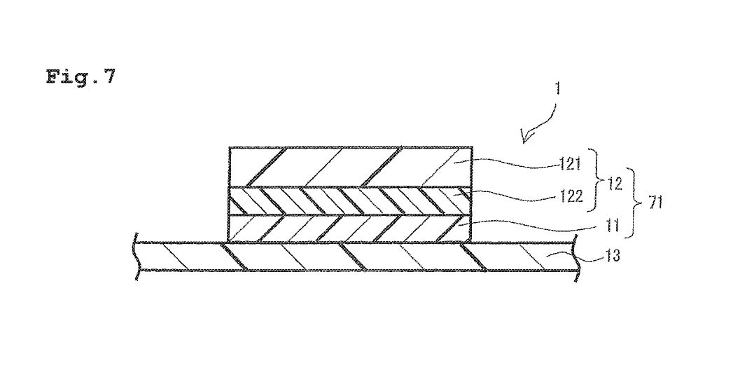

As illustrated in FIG. 7, the whole of a bonding surface of the dicing tape 12 contacts the rear surface-protective film 11. The pressure-sensitive adhesive layer 122 of the dicing tape 12 preferably has a property of being cured by radial rays.

### Modified Example 2

The contact region 122A of the pressure-sensitive adhesive layer 122 has a property of being cured by radial rays. The peripheral region 122B of the pressure-sensitive adhesive layer 122 also has a property of being cured by radial rays.

### Modified Example 3

The contact region 122A of the pressure-sensitive adhesive layer 122 is cured by radial rays. The peripheral region 122B of the pressure-sensitive adhesive layer 122 is also cured by radial rays.

### Modified Example 4

The rear surface-protective film 11 is in a multilayered form which includes a first layer and a second layer disposed on the first layer.

### Other Modified Examples

Modified Examples 1 to 4 and others may be arbitrarily combined with each other.

### EXAMPLES

Hereinafter, preferred examples of this invention will be demonstratively described in detail. However, materials, blend amounts and others that are described in the examples do not for limiting the gist of the invention to only those unless otherwise specified.

### [Production of Rear Surface-Protective Films]

Components used to produce rear surface-protective films are as follows:

Epoxy resin: “HP-4700”, manufactured by DIC Corporation Phenolic resin: “MEH-7851H”, manufactured by Meiwa Plastic Industries, Ltd.

Acrylic rubber: “TEISAN RESIN SG-P3”, manufactured by Nagase ChemteX Corp.

Silica filler: “SE-2050-MCV” (average primary particle diameter: 0.5 μm) manufactured by Admatechs Co., Ltd.

Colorant 1: “NUBIAN BLACK TN877”, manufactured by Orient Chemical Industries Co., Ltd.

Colorant 2: “SOM-L-0543”, manufacturedby Orient Chemical Industries Co., Ltd.

Colorant 3: “ORIPACS B-35”, manufactured by Orient Chemical Industries Co., Ltd.

In each of the examples, in accordance with blend proportions shown in Table 1, individual components were dissolved into methyl ethyl ketone to prepare a solution of an adhesive composition that had a solid concentration of 22% by weight. The adhesive composition solution was applied onto a peel liner (polyethylene terephthalate film subjected to silicone release treatment and having a thickness of 50 μm). Thereafter, the resultant was dried at 130° C. for 2 minutes to produce each rear surface-protective film. The thickness of the rear surface-protective film is shown in Table 1.

### [Rear Surface-Protective Film Evaluations]

About the rear surface-protective films of the example, evaluations described below were made. The results are shown in Table 1.

### (Total Light Transmittance at Wavelength of 555 nm)

About one of the rear surface-protective films, the total light transmittance (%) at a wavelength of 555 nm was measured under the following conditions:

### <Light Transmittance Measuring Conditions>

Measuring device: ultraviolet-visible near infrared spectrophotometer, V-67 ODS (manufactured by JASCO Corporation)

Speed: 2000 nm/minute

Measuring range: 400 to 1600 nm

Integrating sphere: ISN-723

Spot diameter: 1 cm square

### (Notch Detection)

One of the rear surface-protective films was bonded to an 8-inch mirror wafer at 70° C. When the notch in the resultant was detectable through a digital microscope at a light intensity of 25%, the rear surface-protective film was judged to be ◯; or when the notch was not detectable, the rear surface-protective film was judged to be x.

### (Gel Fraction)

From one of the rear surface-protective films, about 0.1 g of a fraction was sampled and the fraction was precisely weighed (the weight of the sample). The sample was wrapped with a mesh-form sheet, and then the resultant was immersed in about 50 mL of ethanol at room temperature for one week. Thereafter, a matter insoluble in the solvent (the content in the mesh-form sheet) was taken out from ethanol, and then dried at 130° C. for about 2 hours. The dried matter insoluble in the solvent was weighed (the weight of the sample after the immersion and the drying). The gel fraction (%) in the sample was calculated out in accordance with the following equation (a):

Gel fraction (%)=[“the weight of the sample after the immersion and the drying”/“the weight of the sample”]×100 (a)

### Tensile Storage Elastic Modulus:

(Tensile Storage Elastic Modulus)

A dynamic viscoelasticity measuring device “Solid Analyzer RS A2” manufactured by Rheometric was used to measure, in a tensile mode, a tensile storage elastic modulus with a sample (width: 10 mm, length: 22.5 mm, and thickness: 0.2 mm) at a frequency of 1 Hz, a temperature-raising rate of 10° C./minute, and a predetermined temperature (23° C.) in a nitrogen atmosphere.

TABLE 1
(Rear surface-protective films)

| | | | | | Comparative |
|---|---|---|---|---|---|
| | | Example 1 | Example 2 | Example 3 | Example 1 |
| Blend proportions | Epoxy resin (HP-4700) | 9 | 9 | 9 | 9 |
| (part(s) by weight) | Phenolic resin (MEH-7851H) | 12 | 12 | 12 | 12 |
| | Acrylic rubber (SG-P3) | 100 | 100 | 100 | 100 |
| | Silica filler (SE-2050-MCV) | 69 | 69 | 69 | 69 |
| | Colorant 1 (NUBIAN BLACK TN877) | 7 | — | — | — |
| | Colorant 2 (SOM-L-0543) | — | 7 | — | — |
| | Colorant 3 (ORIPACS B-35) | — | — | 7 | 7 |
| Thickness (μm) | | 25 | 25 | 25 | 80 |
| Evaluations | Total light transmittance (% T) | 5 | 10 | 3 | 1 |
| | at 555-nm wavelength | | | | |
| | Notch detection | ◯ | ◯ | ◯ | X |
| | Gel fraction (%) according to | 98 | 97 | 98 | 98 |
| | ethanol extraction | | | | |
| | Tensile storage elastic modulus | 1.7 | 1.5 | 1.9 | 1.9 |
| | (GPa) | | | | |

### Production of Integrated Films

### Example 4

One of the rear surface-protective films obtained in Example 1 was bonded to the dicing tape “V-8AR” manufactured by Nitto Denko Corporation to yield an integrated film.

### Example 5

One of the rear surface-protective films obtained in Example 2 was bonded to the dicing tape “V-8AR” to yield an integrated film.

### Example 6

One of the rear surface-protective films obtained in Example 3 was bonded to the dicing tape “V-8AR” to yield an integrated film.

### Comparative Example 2

One of the rear surface-protective films obtained in Comparative Example 1 was bonded to the dicing tape “V-8AR” to yield an integrated film.

[Evaluations about Integrated Films]

About each of the integrated films, evaluations described below were made. The results are shown in Table 2.

### (Total Light Transmittance at Wavelength of 555 nm)

About each of the integrated films, the total light transmittance (%) at a wavelength of 555 nm was measured under the following conditions:

### <Light Transmittance Measuring Conditions>

Measuring device: ultraviolet-visible near infrared spectrophotometer, V-67 ODS (manufactured by JASCO Corporation)

Speed: 2000 nm/minute

Measuring range: 400 to 1600 nm

Integrating sphere: ISN-723

Spot diameter: 1 cm square

### (Notch Detection)

Each of the integrated films was bonded to an 8-inch mirror wafer at 70° C. When the notch in the resultant was detectable through a digital microscope at a light intensity of 25%, the integrated film was judged to be 0; or when the notch was not detectable, the integrated film was judged to be x.

TABLE 2
(Integrated films)

| | | Example 4 | Example 5 | Example 6 | Comparative Example 2 |
|---|---|---|---|---|---|
| Members | Rear surface- | Rear | Rear | Rear | Rear |
| | protective film | surface-protective | surface-protective | surface-protective | surface-protective |
| | | film of Example 1 | film of Example 2 | film of Example 3 | film of Comparative |
| | | | | | Example 1 |
| | Dicing tape | V-8AR | V-8AR | V-8AR | V-8AR |
| Evaluations | Total light | 5 | 10 | 3 | 1 |
| | transmittance (% T) | | | | |
| | at wavelength of 555 nm | | | | |
| | Notch detection | ◯ | ◯ | ◯ | X |

What is claimed is:

1. An integrated film, comprising:
a dicing tape comprising a substrate and a pressure-sensitive adhesive layer disposed on the substrate, and
a rear surface-protective film for protecting a rear surface of a semiconductor element,
wherein the rear surface-protective film is disposed on the pressure-sensitive adhesive layer,
wherein the rear surface-protective film has a total light transmittance of 3% or more at a wavelength of 555 nm.

2. A film, comprising:
a separator, and
the integrated film according to claim 1 disposed on the separator.

3. A method for producing a semiconductor device, the method comprising:
bonding the integrated film according to claim 1 and a semiconductor wafer to each other.

4. A method for producing a chip, the method comprising:
bonding the integrated film according to claim 1 and a semiconductor wafer to each other.

5. An integrated film, comprising:
a dicing tape comprising a substrate and a pressure-sensitive adhesive layer disposed on the substrate, and
a rear surface-protective film for protecting a rear surface of a semiconductor element,
wherein the rear surface-protective film is disposed on the pressure-sensitive adhesive layer,
wherein the integrated film has a total light transmittance of 3% or more at a wavelength of 555 nm.

6. A film, comprising:
a separator, and
the integrated film according to claim 5 disposed on the separator.

7. A method for producing a semiconductor device, the method comprising:
bonding the integrated film according to claim 5 and a semiconductor wafer to each other.

8. A method for producing a chip, the method comprising:
bonding the integrated film according to claim 5 and a semiconductor wafer to each other.
